(19) United States
(12) Patent Application Publication
(10) Pub. No.: US 2007/0245218 A1
(43) Pub. Date: Oct. 18, 2007

(54) Semiconductor integrated circuit and record player

(75) Inventor: Naohiro Nishikawa, Tokyo (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/699,006

(22) Filed: Jan. 29, 2007

(30) Foreign Application Priority Data
Mar. 24, 2006 (JP) 2006-82451

(51) Int. Cl. G11C 29/00

(52) U.S. Cl. 714/763

(57) ABSTRACT

The present invention provides a technique capable of performing a process for encoding data read from a first storing medium and writing the encoded data to a second storing medium seemingly at high speed and, moreover, excellently protecting the copyright of the data. A semiconductor integrated circuit includes: a first processor for performing primary encoding on data read from a first storing medium, thereby forming a temporary file in a second storing medium; and a second processor for performing secondary encoding on the temporary file so as to be converted to compressed stream data, thereby enabling the temporary file and the compressed stream data to be reproduced. Reproduction of the data in the second storing medium is enabled on completion of the primary encoding, so that the process for encoding data read from the first storing medium and writing the encoded data to the second storing medium can be performed seemingly at high speed. Since the temporary file is subjected to the primary encoding, the copyright of the data is protected.

### BACKGROUND OF THE INVENTION

The present invention relates to a record player for recording audio data or video data and capable of reproducing the audio data or video data as necessary.

A technique is known, in which audio data or video data read from a first storing medium such as a CD (Compact Disc) or DVD (Digital Versatile Disc) is recorded into a second storing medium such as a hard disk drive of a personal computer system, and the recorded data is read and reproduced as necessary (refer to, for example, FIG. 1 and the like in Japanese Unexamined Patent Publication No. 2001-210007).

According to the technique, data supplied from a data supply source is temporarily stored as uncompressed data in the original data format into a storage. The stored uncompressed data is processed when a compressing-encoding/decompressing-decoding apparatus is available, and the processed data is stored as compressed data. Arbitrary compressed data stored in the storage or data being recorded can be reproduced.

### SUMMARY OF THE INVENTION

In the conventional technique, however, since audio data or video data read from a storing medium such as a CD or DVD is temporarily stored in the original data format (in a state where data is not encoded) in a hard disk, in the case where the encoding process is interrupted when the user operates a stop button or the like before completion of the process, the audio data or video data may remain in the original data format in the hard disk. This is not preferable from the viewpoint of copyright of the audio data or video data. To address the problem, if the audio data or video data read from the recording medium such as CD or DVD is encoded, and encoded data is recorded on a hard disk, even in the case where the encoding process is interrupted, the audio data or video data can be prevented from remaining in an uncompressed/un-enciphered state in the hard disk, so that the copyright of the data is protected. However, the process of encoding audio data or video data read from a recording medium such as CD or DVD is the bottleneck, and the whole processing time becomes undesirably long. It is caused by insufficient throughput of a CPU (Central Processing Unit) for performing encoding or an LSI dedicated to encoding. Although the throughput of the CPU for performing encoding or the LSI dedicated to encoding may be improved to speed of reading data from a recording medium such as CD or DVD, it is disadvantageous from the viewpoint of cost and it is not realistic.

An object of the invention is to provide a technique capable of performing a process for encoding data read from a first storing medium and writing the encoded data to a second storing medium seemingly at high speed and, moreover, excellently protecting the copyright of the data.

The above and other objects and novel features of the present invention will become apparent from the description of the specification and the appended drawings.

An outline of representative one of inventions disclosed in the application will be briefly described as follows.

(1) A semiconductor integrated circuit capable of performing a process for storing data read from a first storing medium to a second storing medium different from the first storing medium, includes: a first processor for performing primary encoding on data read from the first storing medium, thereby forming a temporary file in the second storing medium; and a second processor for performing secondary encoding on the temporary file so as to be converted to compressed stream data. The temporary file and the compressed stream data can be reproduced. The encoding denotes coding of data on the basis of a predetermined rule and is, for example, compression or enciphering of data. The primary encoding can be set as enciphering of data, and the secondary encoding can be set as compression of data.

With the means, the first processor performs the primary encoding on data read from the first storing means and stores the resultant data as a temporary file in the second storing means. The second processor converts the temporary file to compressed stream data by the secondary encoding. As described above, the process for obtaining compressed stream data is performed by the primary encoding in the first processor and the secondary encoding in the second processor. Moreover, the temporary file and the compressed stream data can be reproduced. Consequently, reproduction of data in the second storing medium is enabled on completion of the primary encoding and the user does not have to wait for completion of the secondary encoding. Thus, the process for encoding data read from the first storing medium and writing the encoded data to the second storing medium can be performed seemingly at high speed. Moreover, since the temporary file has been subjected to the primary encoding process, even if the encoding process is interrupted by erroneous operation on the stop button of the user, there is no possibility that audio data or video data remains in the original data format in the second storing medium. Thus, the copyright of the data is protected.

(2) The semiconductor integrated circuit as described in (1) can further include: a primary decoder capable of decoding a temporary file in the second storing medium; a secondary decoder capable of decoding compressed stream data in the second storing medium; and an interface capable of outputting a result of decoding of the primary decoder and a result of decoding of the secondary decoder to the outside so as to be reproduced.

(3) In the semiconductor integrated circuit as described in (2), the primary decoder can decode the temporary file in the second storing medium during encoding in the second processor.

(4) The semiconductor integrated circuit as described in (1) can further include a file management system capable of erasing a corresponding temporary file on completion of the secondary encoding in the second processor.

(5) In the semiconductor integrated circuit as described in (1), the first and second processors are formed on different chips.

(6) The semiconductor integrated circuit as described in (5) may further include: a first chip on which the first processor is formed; and a second chip on which the second processor is formed. In this case, the operation frequency of the second chip is set to be higher than the operation frequency in the first processor.

(7) A record player includes: a first storing medium; a second storing medium different from the first storing medium; and a semiconductor integrated circuit capable of performing a process for storing data read from the first storing medium into the second storing medium. The semiconductor integrated circuit includes: a first processor for performing primary encoding on data read from the first storing medium, thereby forming a temporary file in the second storing medium; and a second processor for performing secondary encoding on the temporary file so as to be converted to compressed stream data. The temporary file and the compressed stream data can be reproduced.

With the means, the first processor performs the primary encoding on data read from the first storing means and stores the resultant data as a temporary file in the second storing means. The second processor converts the temporary file to compressed stream data by the secondary encoding. As described above, the process for obtaining compressed stream data is performed by the primary encoding in the first processor and the secondary encoding in the second processor. Moreover, the temporary file and the compressed stream data can be reproduced. Consequently, reproduction of data in the second storing medium is enabled on completion of the primary encoding and the user does not have to wait for completion of the secondary encoding. Thus, the process for encoding data read from the first storing medium and writing the encoded data to the second storing medium can be performed seemingly at high speed. Moreover, since the temporary file has been subjected to the primary encoding process, even if the encoding process is interrupted by erroneous operation on the stop button of the user, there is no possibility that audio data or video data remains in the original data format in the second storing medium. Thus, the copyright of the data is protected.

(8) The record player as described in (7) may further include: a primary decoder capable of decoding a temporary file in the second storing medium; a secondary decoder capable of decoding compressed stream data in the second storing medium; and an interface capable of outputting a result of decoding of the primary decoder and a result of decoding of the secondary decoder to the outside so as to be reproduced.

(9) In the record player as described in (8), the primary decoder can decode the temporary file in the second storing medium during encoding in the second processor.

(10) The record player as described in (7) may further include a file management system capable of erasing a corresponding temporary file on completion of the secondary encoding in the second processor.

(11) In the record player as described in (7), the first and second processors are formed on different chips.

(12) The record player as described in (7) may further include: a first chip on which the first processor is formed; and a second chip on which the second processor is formed. The operation frequency of the second chip can be set to be higher than the operation frequency in the first processor.

(13) The record player as described in (10) may further include a display capable of displaying output information of the semiconductor integrated circuit. The file management system can convert a file name prior to the secondary encoding to a file name subjected to the secondary encoding and display the converted file name on the display.

An effect obtained by representative one of the inventions disclosed in the application will be briefly described as follows.

The present invention can provide a technique capable of performing a process for encoding data read from a first storing medium and writing the encoded data to a second storing medium seemingly at high speed and, moreover, excellently protecting the copyright of the data.

### BRIEF DESCRIPTION OF THE DRAWINGS

FIG. 1 is a block diagram showing a configuration example of a record player according to the present invention.

FIGS. 2A and 2B are diagrams showing operations of a main part in the record player.

FIG. 3 is a flowchart showing main operations of a ripping process in the record player.

FIG. 4 is a diagram showing main operation in the record player.

FIG. 5 is another diagram showing main operation in the record player.

FIG. 6 is another diagram showing main operation in the record player.

FIG. 7 is a flowchart showing main operations of data reproduction in the record player.

FIG. 8 is a diagram showing the flow of data in the record player.

FIG. 9 is a block diagram showing another configuration example of the record player.

### DETAILED DESCRIPTION OF THE PREFERRED EMBODIMENTS

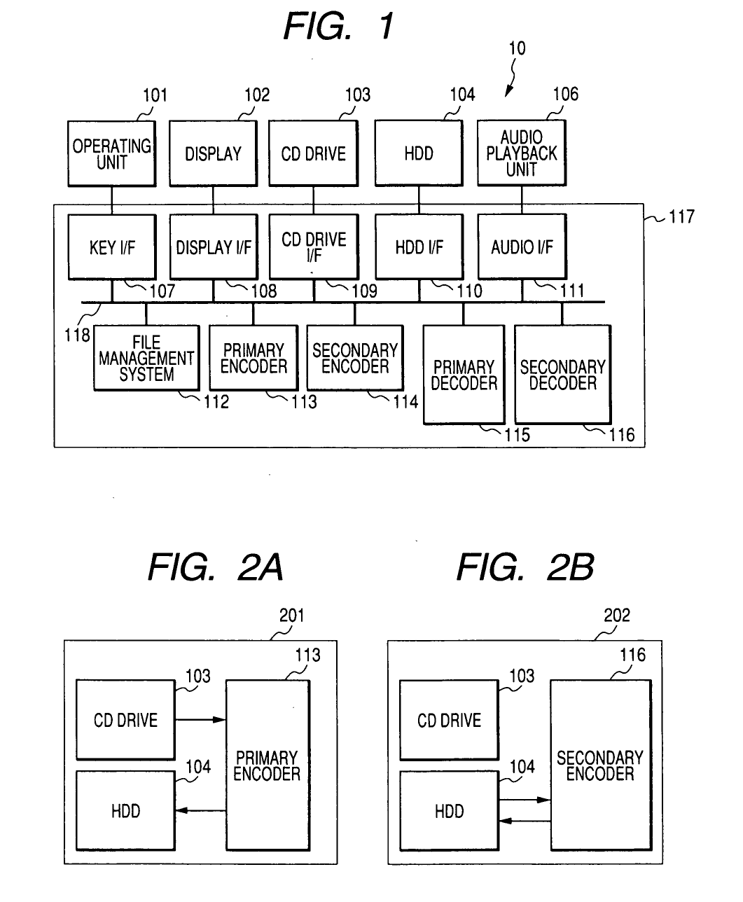

FIG. 1 shows a configuration example of a record player according to the invention.

A record player 10 is an audio unit in a car navigation system and includes an operating unit 101 such as a switch, a display 102 for displaying an image and various information, a CD drive 103 capable of reading data recorded in a CD, a hard disk drive (HDD) 104 capable of storing various data, an audio playback unit 106 capable of performing audio playback, and an LSI (semiconductor integrated circuit) 117 for record and playback. A CD inserted in the CD drive 103 is an example of a first storing medium in the invention, and the hard disk drive 104 is an example of a second storing medium in the invention.

The LSI 117 for record and playback includes, although not limited, a key interface (I/F) 107, a display interface 108, a CD drive interface 109, a hard disk drive interface (HDD I/F) 110, an audio interface 111, a file management system 112, a primary encoder 113, a secondary encoder 114, a primary decoder 115, a secondary decoder 116, and a system bus 118 for connecting the components so that signals can be transmitted/received to/from each other. The primary encoder 113 is an example of a first processor in the invention, and the secondary encoder 114 is an example of a second processor in the invention.

The key interface 107 can fetch key input data from the operating unit 101. The display interface 108 can transmit display data to the display 102. The display 102 is, although not limited, a liquid crystal display. A CD (not shown) as a recording medium can be loaded/unloaded to/from the CD drive 103. In the state where a CD is inserted in the CD drive 103, audio data can be read from the CD. The CD drive interface 109 can fetch audio data read from the CD in the CD drive 103. The hard disk drive 104 can write/read data to/from a magnetic disk as a built-in recording medium. The hard disk interface 110 can transmit/receive audio data to/from the hard disk drive 104. The audio interface 111 can transmit audio data to the audio playback unit 106. The file management system 112 manages various data files dealt in the LSI 117 for record and playback. The primary encoder 113 performs primary encoding of audio data transmitted from the CD drive 103 via the CD drive interface 109. The encoding denotes coding of data on the basis of a predetermined rule. In the embodiment, the primary encoding is, although not limited, an enciphering process. The process result is transmitted to the hard disk drive 104 via the hard disk interface 110, and is written as a temporary file in a predetermined area. The primary decoder 115 decodes the encoded data received from the hard disk drive 104 via the hard disk interface 110 to the original audio data (unenciphered audio data). The secondary encoder 114 performs secondary encoding on the audio data decoded by the primary decoder 115. In the embodiment, the secondary encoding is compression of data and is, although not limited, AAC (Advanced Audio Codec) or MP3 (MPEG1 Audio Layer-3) as known audio compressing standards. The result of the secondary encoding is stored again in the predetermined area in the hard disk drive 104. In such a manner, the temporary file in the hard disk drive 104 is converted to compressed stream data.

In the configuration, encoding process performed in the case where the audio data fetched from the CD drive 103 is compressed and enciphered and the resultant data is stored in the hard disk drive 104 is divided into the primary encoding and the secondary encoding.

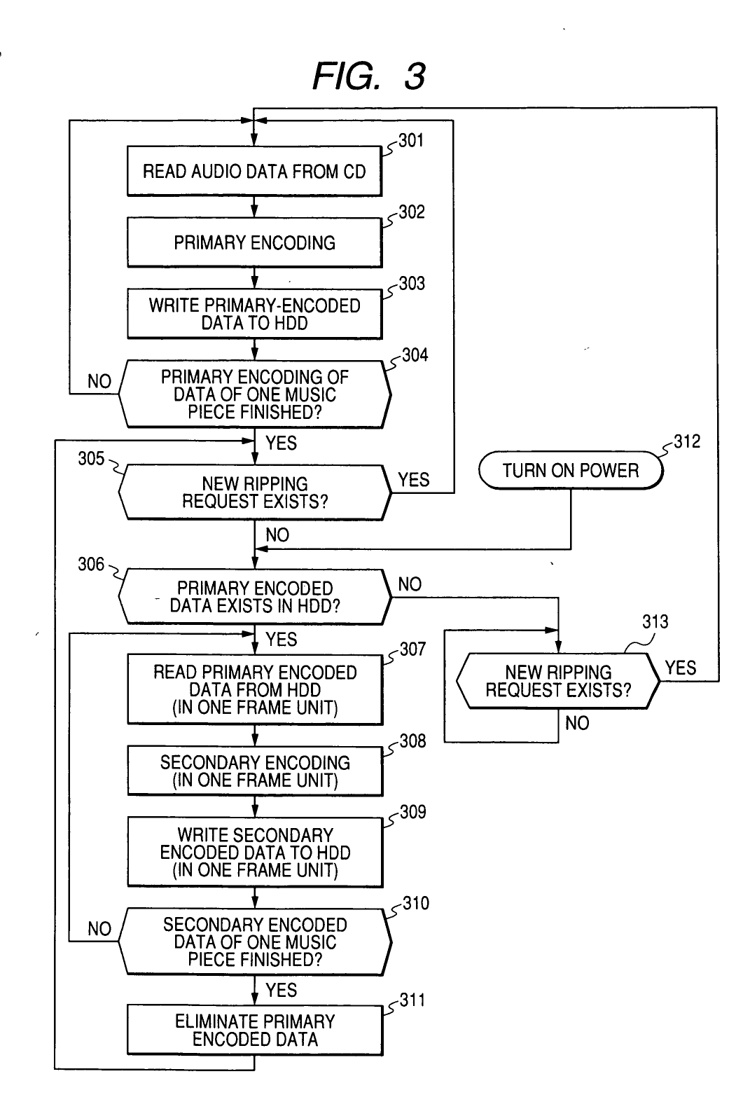

Specifically, as shown in FIG. 2A, at the time of reading data from the CD drive 103, the primary encoding is performed by the primary encoder 113. After completion of the reading of data from the CD drive 103, the secondary encoding is performed by the secondary encoder 114.

Preferably, a primary encoding process amount in the primary encoder 113 is smaller than the secondary encoding process amount in the secondary encoder 114, and the encoding process is performed at a speed equal to or higher than speed of reading data from the CD drive 103. Consequently, as shown in FIG. 2A, at the time of reading data from the CD drive 103, by performing primary encoding on an amount smaller than the processing amount, the reading speed is prevented from being lowered and, after completion of reading of data from the CD drive 103, the secondary encoding is performed. The user can take the CD out from the CD drive 103 on completion of the primary encoding, and an effect similar to shortening of the encoding time is produced seemingly. The data subjected to the primary encoding in the primary encoder 113 is written to the hard disk drive 104 and the audio data (uncompressed/unenciphered data) read from the CD is not written in the original format. Consequently, even if the encoding process is interrupted for some reason, audio data can be prevented from remaining in an uncompressed/unenciphered state in the hard disk drive 104.

The encoding process itself may be performed in the primary encoding and the secondary encoding. However, the process amount of the primary encoding varies according to the audio compressing method (AAC, MP3, or the like). Therefore, the enciphering process is applied as the primary encoding.

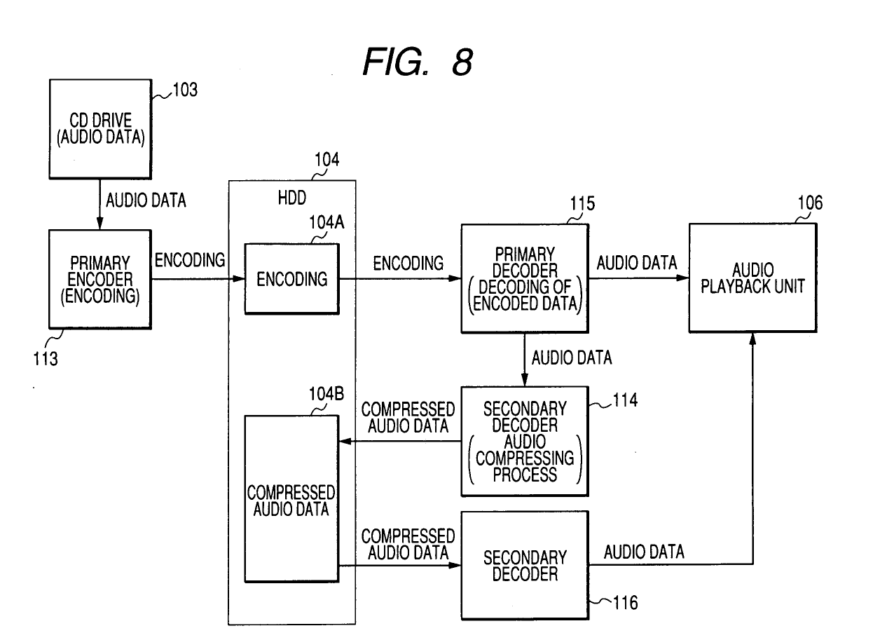

FIG. 8 shows the flow of data in the record player 10 illustrated in FIG. 1.

In FIG. 8, the interfaces 109, 110, and 111 are not shown.

The flow of data accompanying the primary encoding process is as follows. Audio data is read from a CD by the CD drive 103 and is enciphered by the primary encoder 113, and the enciphered audio data is stored in a first area in the hard disk drive 104.

The flow of data accompanying the secondary encoding process is as follows. Enciphered data 104A is read from the hard disk drive 104 and is deciphered by the primary decoder 115, thereby converting the enciphered data to audio data. After that, the audio data is compressed by the secondary encoder 114, and the compressed audio data is stored in a second area in the hard disk drive 104. Since the stored secondary encoded data 104B is data generally compressed by an irreversible compressing method, even if the data is read falsely, there is no problem in copyright. The secondary encoding in the secondary encoder 114 is conformed with the audio compressing standard (AAC, MP3, or the like).

In the case of reproducing the primary encoded data (enciphered data) 104 stored in the hard disk drive 104, the enciphered data 104A is read from the hard disk drive 104, deciphered in the primary decoder 115 to audio data, and the audio data is transferred to the audio playback unit 106 and reproduced. In the case of reproducing the secondary encoded data (audio compressed data) 104B stored in the hard disk drive 104, the audio compressed data 104B is read from the hard disk drive 104 and decompressed to audio data in the secondary decoder 116. The audio data is transferred to the audio playback unit 106 and reproduced.

The flow of data as described above is controlled by the file management system 112.

The primary encoder 113 and the secondary encoder 114 can be realized by a single processing unit constructed by a CPU (Central Processing Unit), a nonvolatile memory in which a program for operating the CPU is stored, and a RAM used as a work area in the CPU. FIG. 3 shows the flow of the processes in this case.

First, the power of the record player 10 is turned on (312), and whether primary-encoded audio data exists in the hard disk drive 104 or not is determined (306). In the case where it is determined that the primary-encoded audio data does not exist in the hard disk drive 104 (“No”), whether there is a new ripping request or not is determined (313). If it is determined that there is a new ripping request (“Yes”), audio data is read from a CD by the CD drive 103 (301) and transferred to the primary encoder 113, and the primary encoding process is performed (302). The resultant data is written in the hard disk drive 104 (303). After that, whether the primary encoding has been finished on data of the first music piece or not is determined (304). In the case where it is determined that the primary encoding has not been finished on the data of the first music piece (“No”), the routine shifts to the process in the step 301. In the case where it is determined in the step 304 that the primary encoding on the data of the first music piece has been finished (“Yes”), whether there is a new ripping request or not is determined (305). In the case where it is determined that there is a new ripping request (“Yes”), the routine shifts to the process in the step 301. In the case where it is determined in the step 305 that there is no new ripping request (“No”), whether the primary-encoded data exists in the hard disk drive 104 or not is determined (306). In the case where it is determined that the primary encoded data exists in the hard disk drive 104 (“Yes”), the primary-encoded data is read from the hard disk drive 104 on a frame unit basis (307) and is transferred to the secondary encoder 114 where the secondary encoding process is performed on the frame unit basis (308). The frame is defined in the audio compressing standard. For example, in the case of the AAC, one frame consists of 1,024 samples. The result of the secondary encoding process is written on the frame unit basis to the hard disk drive 104 (309). Whether the primary encoding on the data of the first music piece has been finished or not is determined (310). In the case where it is determined that the primary encoding on data of the first music piece has not been finished (“No”), the routine shifts to the process in the step 307. In the case where it is determined in the step 310 that the primary encoding on the data of the first music piece has been finished (“Yes”), the primary encoded data in the hard disk drive 104 is erased (311), and the routine shifts to the process in the step 305.

As described above, the secondary encoding process is executed in the finely divided units, that is, on the frame unit basis (for example, 1,024 samples in the case of the AAC). When there is a new ripping request, the secondary encoding process is interrupted and the primary encoding process is performed. The secondary encoding process is performed in time during which the primary encoding process is not performed (unoccupied time of the CPU). Consequently, the primary encoder 113 and the secondary encoder 114 can be realized by a single CPU (Central Processing Unit). After the secondary encoding process is finished, the primary encoded data which becomes unnecessary is erased. Therefore, the free space in the hard disk drive 104 can be prevented from being occupied by unnecessary data.

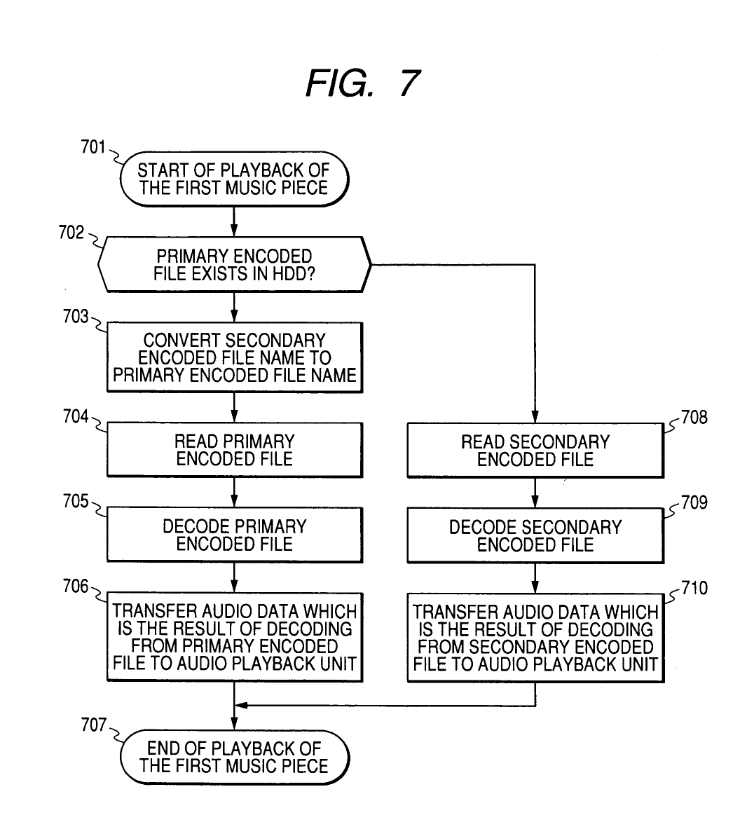

Next, reproduction of audio data will be described with reference to the flowchart of FIG. 7.

The audio data becomes reproducible on completion of the primary encoding of the primary encoder 113.

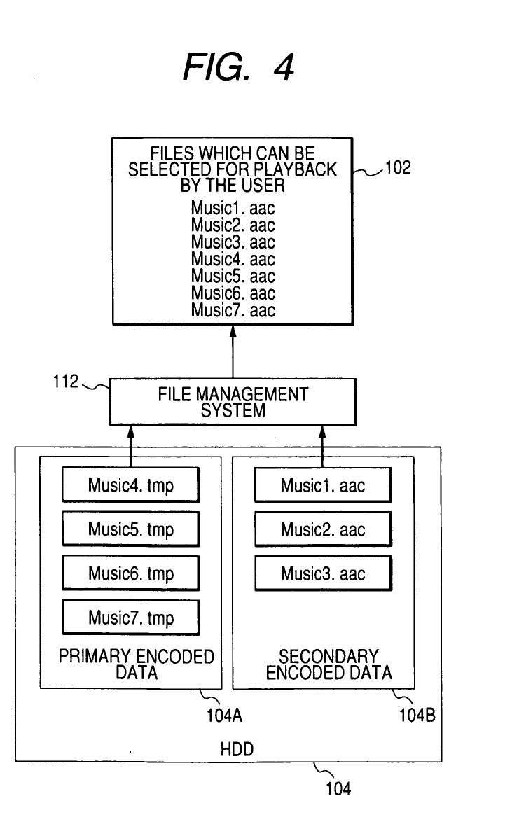

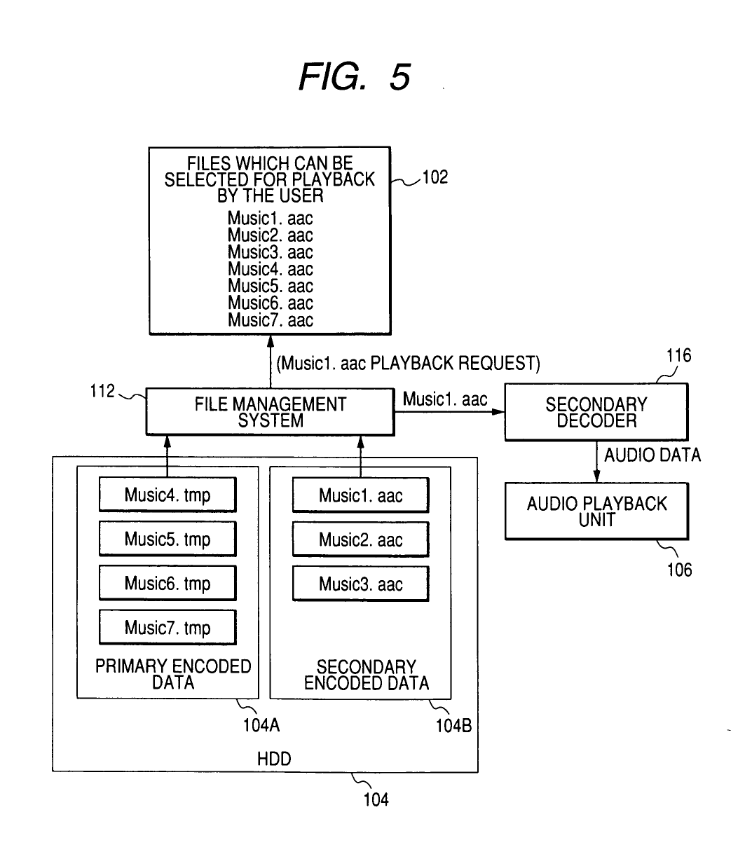

The file name of an audio data file which can be reproduced at present can be displayed on the display 102 on the basis of management information in the file management system 112. By selecting an arbitrary file name from file names displayed on the display 102 via the operating unit 101, the user can reproduce the data file. The file management system 112 changes the file name of the primary encoded file (file output from the primary encoder) so that the user can see it in a manner similar to the secondary encoded file (file output from the secondary encoder). For example, as shown in FIG. 4, in the case where the primary encoded data (files with the extension tmp) 104A and the secondary encoded data (files with the extension aac) 104B are stored in the hard disk drive 104, the file management system 112 changes the extension of each of the files in the primary encoded data 104A in file information to be output to the display 102 from “tmp” to “aac”. By the operation, all of files are displayed as if they are secondary-encoded files on the display 102. The user can select a file desired to be reproduced from a plurality of files displayed. The file selecting operation is performed by the operating unit 101. The flow of data changes depending on whether the secondary encoding on the selected file has been completed or not.

Specifically, in the case where the user instructs start of reproduction of the first music piece (701), the file management system 112 determines whether a primary encoded file exists in the hard disk drive 104 or not (702). In the case where it is determined that no primary encoded file exists in the hard disk drive 104 (“No”), it denotes that the secondary encoding has been completed on the file, so that a secondary encoded file in the hard disk drive 104 is read (708) and decoded by the secondary decoder 116 (709). The audio data as the result of decoding of the secondary encoded file is transferred to the audio playback unit 106 (710).

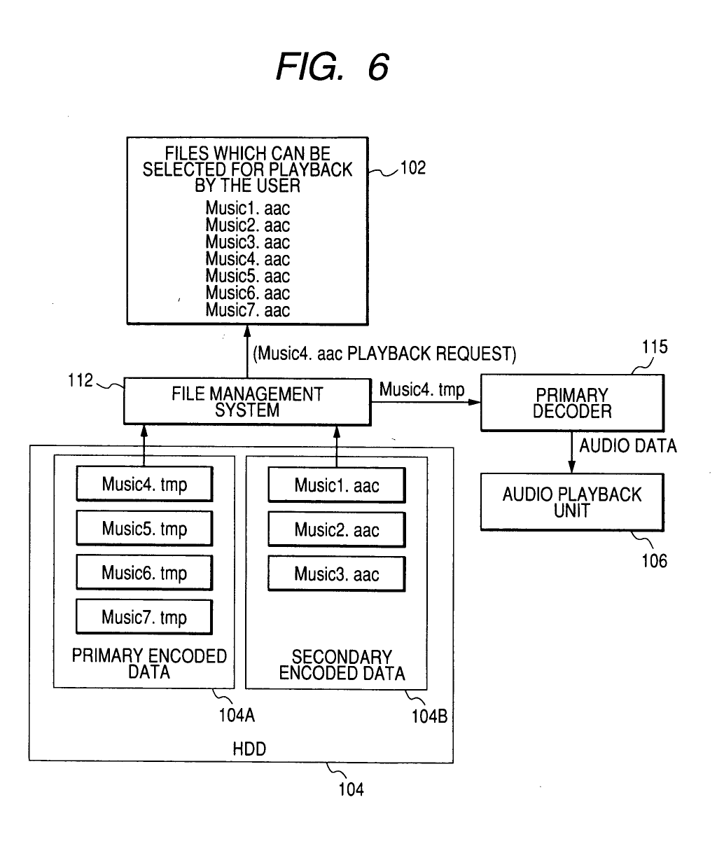

For example, as shown in FIG. 5, in the case where “Music1.aac” is selected as a reproduction request file, the file management system 112 reads “Music1.aac” as the secondary encoded data 104B from the hard disk drive 104 and outputs it to the secondary decoder 116. Consequently, “Music1.aac” is decoded by the secondary decoder 116 and, as a result, audio data is obtained. The audio data is reproduced by the audio playback unit 106 and reproduction of the first music piece is finished (707).

On the contrary, in the case where it is determined in the step 702 that a primary encoded file exists in the hard disk drive 104 (“Yes”), the secondary encoded file is converted to a primary encoded file name (703), the primary encoded file is read (704) and is decoded by the primary decoder 115 (705), thereby obtaining audio data. The audio data is transferred to the audio playback unit 106.

For example, as shown in FIG. 6, when “Music4.aac” is selected as a reproduction request file, since the secondary encoding on the file has not been completed yet, the file management system 112 reads “Music4.tmp” as the primary encoded file 104A and outputs it to the primary decoder 115. “Music4.tmp” is decoded by the primary decoder 115, thereby obtaining audio data. The audio data is reproduced by the audio playback unit 106, and reproduction of the first music piece is finished (707).

As described above, the user can reproduce audio data on completion the primary encoding without awareness of whether the secondary encoding on the selected file has been completed or not.

By the foregoing embodiments, the following effects can be obtained.

(1) The primary encoder 113 performs primary encoding on data read from a ROM. The result of encoding is stored as a temporary file in the hard disk drive 104. The primary decoder 115 decodes the temporary file. The result of decoding is encoded by the secondary encoder 114, thereby converting the decoded data to compressed stream data. Since the temporary file and the compressed stream data can be reproduced, the data in the hard disk drive 104 becomes reproducible on completion of the primary encoding, so that the user does not have to wait for completion of the secondary encoding. Consequently, the process of encoding data read from a CD and writing the encoded data to the hard disk drive 104 can be performed at high speed seemingly. Moreover, since the temporary file is a file subjected to the primary encoding process, even when the encoding process is interrupted by, for example, erroneous operation on the stop button of the user, there is no possibility that audio data or video data remains in the original data format in the second storing medium. Therefore, the copyright of the data is protected.

(2) Since the process in the primary encoder 113 is enciphering and the process in the secondary encoder 114 is data compression, time required for the process in the primary encoder 113 can be constant irrespective of the compressing method in the secondary encoder 114.

The inventions achieved by the inventors herein have been concretely described above. However, obviously, the present invention is not limited to the above but can be variously modified without departing from the gist.

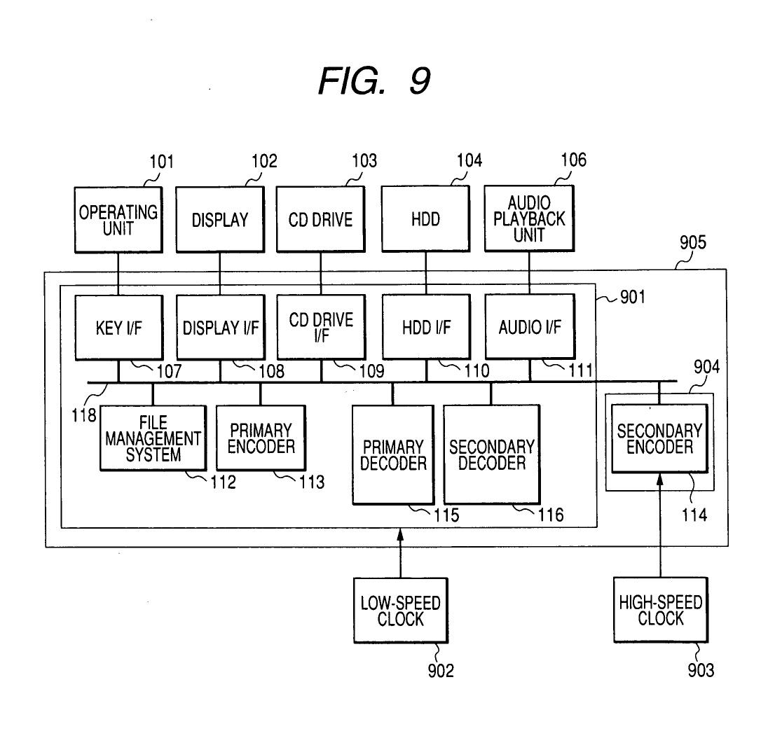

For example, although the primary encoder 113 and the secondary encoder 114 are formed by the same processing units in the foregoing embodiment, the primary encoder 113 and the secondary encoder 114 can be also realized by the same hardware dedicated to encoding. It is also possible to construct one of the primary encoder 113 and the secondary encoder 114 by the hardware dedicated to encoding, and construct the other encoder by the processing unit as shown in FIG. 9.

An LSI (semiconductor integrated circuit) 905 for record and playback shown in FIG. 9 is largely different from the LSI 117 for record and playback shown in FIG. 1 with respect to the point that only the secondary encoder 114 is formed by a second chip 904 different from a first chip 901. The secondary encoder 114 is connected to the components in the first chip 901 via the system bus 118. The first chip 901 operates synchronously with a low-speed clock signal 902 supplied from the outside, and the secondary encoder 114 operates synchronously with a high-speed clock signal 903 supplied from the outside. With the configuration, the secondary encoding process in the secondary encoder 114 is performed at higher speed as compared with the encoding process in the primary encoder 113. Since it is sufficient to perform the encoding process in the primary encoder 113 at CD reading speed in the CD drive 103, by performing the encoding process in the primary encoder 113 synchronously with the low-speed clock signal 902, the power consumption in the first chip 901 can be reduced.

In the case where the primary encoder 113 and the secondary encoder 114 are separately constructed by the hardware dedicated to encoding as described above, by employing the configuration such that the primary decoder 115 is provided and a decoded output of the primary decoder 115 is encoded by the secondary encoder 114, a general chip can be applied as the secondary encoder 113. The configuration is advantageous from the viewpoint of reducing the manufacture cost of the record player.

Although a CD is used as the first recording medium in the foregoing embodiment, the invention is not limited to the embodiment. For example, a DVD can be used as the first recording medium.

Although the case where the present invention achieved by the inventors herein is applied to an audio unit in a car navigation system in the field of utilization as the background of the invention has been described above, the invention is not limited to the case but can be widely applied to various devices handling audio data and video data.

The present invention can be applied under condition that at least data read from a storing medium is stored into another storing medium.

What is claimed is:

1. A semiconductor integrated circuit capable of performing a process for storing data read from a first storing medium to a second storing medium different from the first storing medium, comprising:
a first processor for performing primary encoding on data read from the first storing medium, thereby forming a temporary file in the second storing medium; and
a second processor for performing secondary encoding on the temporary file so as to be converted to compressed stream data,
wherein the temporary file and the compressed stream data can be reproduced.

2. The semiconductor integrated circuit according to claim 1, further comprising:
a primary decoder capable of decoding a temporary file in the second storing medium;
a secondary decoder capable of decoding compressed stream data in the second storing medium; and
an interface capable of outputting a result of decoding of the primary decoder and a result of decoding of the secondary decoder to the outside so as to be reproduced.

3. The semiconductor integrated circuit according to claim 2, wherein the primary decoder can decode the temporary file in the second storing medium during encoding in the second processor.

4. The semiconductor integrated circuit according to claim 1, further comprising a file management system capable of erasing a corresponding temporary file on completion of the secondary encoding in the second processor.

5. The semiconductor integrated circuit according to claim 1, wherein the first and second processors are formed over different chips.

6. The semiconductor integrated circuit according to claim 5, further comprising:
a first chip over which the first processor is formed; and
a second chip over which the second processor is formed,
wherein the operation frequency of the second chip is set to be higher than the operation frequency in the first processor.

7. A record player comprising:
a first storing medium;
a second storing medium different from the first storing medium; and
a semiconductor integrated circuit capable of performing a process for storing data read from the first storing medium into the second storing medium,
wherein the semiconductor integrated circuit includes:
a first processor for performing primary encoding on data read from the first storing medium, thereby forming a temporary file in the second storing medium; and
a second processor for performing secondary encoding on the temporary file so as to be converted to compressed stream data, and
wherein the temporary file and the compressed stream data can be reproduced.

8. The record player according to claim 7, further comprising:
a primary decoder capable of decoding a temporary file in the second storing medium;
a secondary decoder capable of decoding compressed stream data in the second storing medium; and
an interface capable of outputting a result of decoding of the primary decoder and a result of decoding of the secondary decoder to the outside so as to be reproduced.

9. The record player according to claim 8, wherein the primary decoder can decode the temporary file in the second storing medium during encoding in the second processor.

10. The record player according to claim 7, further comprising a file management system capable of erasing a corresponding temporary file on completion of the secondary encoding in the second processor.

11. The record player according to claim 7, wherein the first and second processors are formed over different chips.

12. The record player according to claim 11, further comprising:
a first chip over which the first processor is formed; and
a second chip over which the second processor is formed,
wherein the operation frequency of the second chip is set to be higher than the operation frequency in the first processor.

13. The record player according to claim 10, further comprising a display capable of displaying output information of the semiconductor integrated circuit,
wherein the file management system converts a file name prior to the secondary encoding to a file name subjected to the secondary encoding and displays the converted file name on the display.
